(19) United States
(12) Patent Application Publication
(10) Pub. No.: US 2015/0187438 A1
(43) Pub. Date: Jul. 2, 2015

(54) SEMICONDUCTOR MEMORY APPARATUS AND TEST METHOD USING THE SAME

(71) Applicant: SK hynix Inc., Icheon-si (KR)

(72) Inventors: Yu Ri LIM, Icheon-si (KR); Jae Il KIM, Icheon-si (KR)

(73) Assignee: SK hynix Inc., Icheon-si (KR)

(21) Appl. No.: 14/248,460

(22) Filed: Apr. 9, 2014

(30) Foreign Application Priority Data
Dec. 30, 2013 (KR) 10-2013-0167031

(51) Int. Cl. G11C 29/12; G06F 1/12

(52) U.S. Cl. CPC G11C 29/12015; G06F 1/12

(57) ABSTRACT

A semiconductor memory apparatus includes first data outputted from a first data storage region; second data outputted from a second data storage region; a data comparison block configured to perform a comparison to determine whether the first data and the second data are the same, and generate a comparison result signal; a timing control block configured to latch the comparison result signal in response to a clock and a latency signal, and output a comparison signal; and a data output block configured to receive a test signal and invert the first data in response to the comparison signal and output data.

### CROSS-REFERENCES TO RELATED APPLICATION

The present application claims priority under 35 U.S.C. §119(a) to Korean application number 10-2013-0167031, filed on Dec. 30, 2013, in the Korean Intellectual Property Office, which is incorporated herein by reference in its entirety.

### TECHNICAL FIELD

Various embodiments relate to a semiconductor integrated circuit, and more particularly, to a semiconductor memory apparatus.

### BACKGROUND

A semiconductor memory apparatus is configured to store data and output stored data.

A semiconductor memory apparatus may be tested in terms of whether data are properly stored and outputted. In a test, in order to test whether data is normally stored and stored data are normally outputted, data is inputted through data input paths and is stored, and stored data is outputted through data output paths.

In order to shorten a test time, the same data is inputted and stored in a plurality of data storage regions, and comparisons are made to know whether all the data outputted from the plurality of data storage regions are the same with one another.

A conventional semiconductor memory apparatus is configured to perform a test by outputting a data comparison result through a data output path.

In the conventional semiconductor memory apparatus, a timing at which the data comparison result is outputted in the test is later than a timing at which data are outputted not in the test. This is because an operation for comparing data is added in the test. In a conventional semiconductor memory apparatus, the timing at which the data comparison result is outputted in the test and the timing at which data are outputted not in the test are different from each other.

### SUMMARY

In an embodiment, a semiconductor memory apparatus includes: first data outputted from a first data storage region; second data outputted from a second data storage region; a data comparison block configured to perform a comparison to determine whether the first data and the second data are the same, and generate a comparison result signal; a timing control block configured to latch the comparison result signal in response to a clock and a latency signal, and output a comparison signal; and a data output block configured to receive a test signal and invert the first data in response to the comparison signal and output data.

In an embodiment, a semiconductor memory apparatus includes: a data comparison block configured to determine whether a plurality of first data and a plurality of second data are the same, and generate a comparison result signal; a timing control block configured to latch the comparison result signal in response to a clock and a latency signal, and output a comparison signal; and a data output block configured to determine whether to invert specified data among the plurality of first data, in response to the comparison signal, and output the specified data determined in terms of whether to be inverted or not and the first data which are left by excluding the specified data determined in terms of whether to be inverted or not, as output data, in a test.

In an embodiment, a method for testing a semiconductor memory apparatus includes: storing the same data in a plurality of data storage regions; determining whether data stored in different data storage regions are the same and providing a result; delaying a latency signal by a predetermined cycle of a clock; and latching the is result of the determining and outputting a latched result, in response to a delayed latency signal.

In an embodiment, a system may include: a processor; a chipset configured to couple with the processor; a memory controller configured to receive a request provided from the processor through the chipset; and a semiconductor memory apparatus configured to receive the request and output data to the memory controller, the semiconductor memory apparatus including: first data outputted from a first data storage region; second data outputted from a second data storage region; a data comparison block configured to perform a comparison to determine whether the first data and the second data are the same, and generate a comparison result signal; a timing control block configured to latch the comparison result signal in response to a clock and a latency signal, and output a comparison signal; and a data output block configured to receive a test signal and invert the first data in response to the comparison signal and output output data.

### BRIEF DESCRIPTION OF THE DRAWINGS

Features, aspects, and embodiments are described in to conjunction with the attached drawings, in which:

FIG. 1 is a configuration diagram of a semiconductor memory apparatus in accordance with an embodiment;

FIG. 2 is a configuration diagram of the timing control block shown in FIG. 1;

FIG. 3 is a configuration diagram of the data output block shown in FIG. 1; and

FIG. 4 is a configuration diagram of the selective inversion unit shown in FIG. 3.

FIG. 5 illustrates a block diagram of a system employing the semiconductor memory apparatus in accordance with the embodiments discussed above with relation to FIGS. 1-4.

### DETAILED DESCRIPTION

Hereinafter, a semiconductor memory apparatus and a test method using the same will be described below with reference to the accompanying drawings through various embodiments.

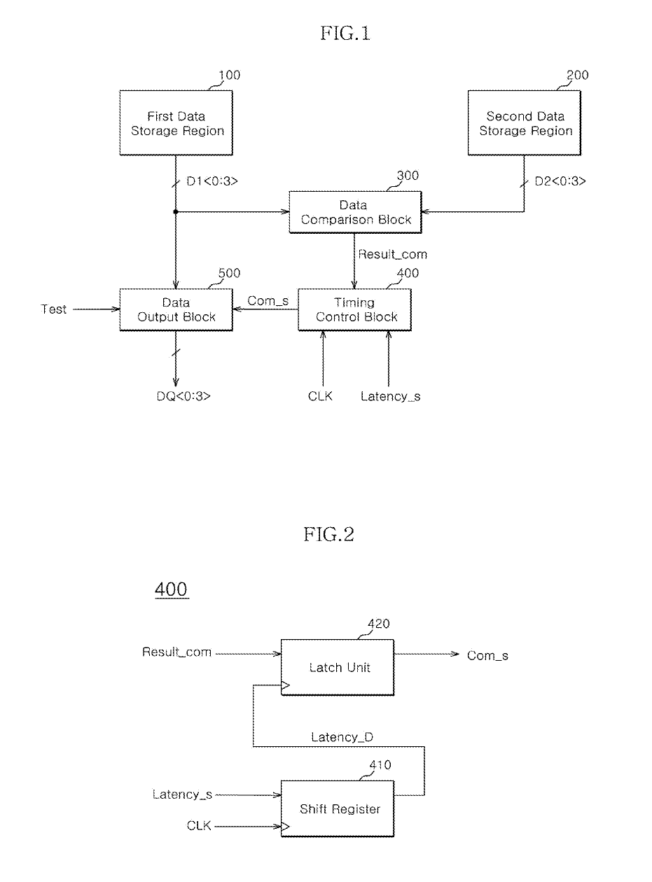

As shown in FIG. 1, a semiconductor memory apparatus in accordance with an embodiment may include a first data storage region 100, a second data storage region 200, a data comparison block 300, a timing control block 400, and a data output block 500.

The first and second data storage regions 100 and 200 may be configured to store inputted data and output stored data in response to external commands. The data outputted from the first data storage region 100 are referred to as a plurality of first data D1<0:3>, and the data outputted from the second data storage region 200 are referred to as a plurality of second data D2<0:3>.

The data comparison block 300 may be configured to perform comparison to know whether the plurality of first data D1<0:3> and the plurality of second data D2<0:3> are the same, and generate a comparison result signal Result_com. The data comparison block 300 may be constituted by an exclusive NOR gate or an exclusive OR gate. For example, the data comparison block 300 may output the comparison result signal Result_com which is enabled, when the plurality of first data D1<0:3> and the plurality of second data D2<0:3> are all the same, and outputs the comparison result signal Result_com which is disabled, when the plurality of first data D1<0:3> and the plurality of second data D2<0:3> are different.

The timing control block 400 may be configured to latch the comparison result signal Result_com in response to a clock CLK and a latency signal Latency_s, and output the latched signal as a comparison signal Com_s. For example, the timing control block 400 delays the latency signal Latency_s by the predetermined cycle of the clock CLK, latches the comparison result signal Result_com in response to the delayed latency signal Latency_s, and outputs the latched signal as the comparison signal Com_s. The latency signal Latency_s, as a signal which is generated when a preset time has passed after a command for outputting the data stored in the semiconductor memory apparatus is inputted, is a signal which may determine the data output timing of the semiconductor memory apparatus. The time by which the latency signal Latency_s is delayed in the timing control block 400 may beset to be the same as a time that is required for the data comparison block 300 to compare the plurality of first data D1<0:3> and the plurality of second data D2<0:3>.

The data output block 500 may be configured to output the plurality of first data D1<0:3> as a plurality of output data DQ<0:3> in a normal operation, that is, not in a test or test mode. The data output block 500 may be configured to output the plurality of first data D1<0:3> by inverting data specified among them, in response to the comparison signal Com_s in the test. The data output block 500 may perform in a normal operation mode or operate in a test or test mode in response to a test signal Test.

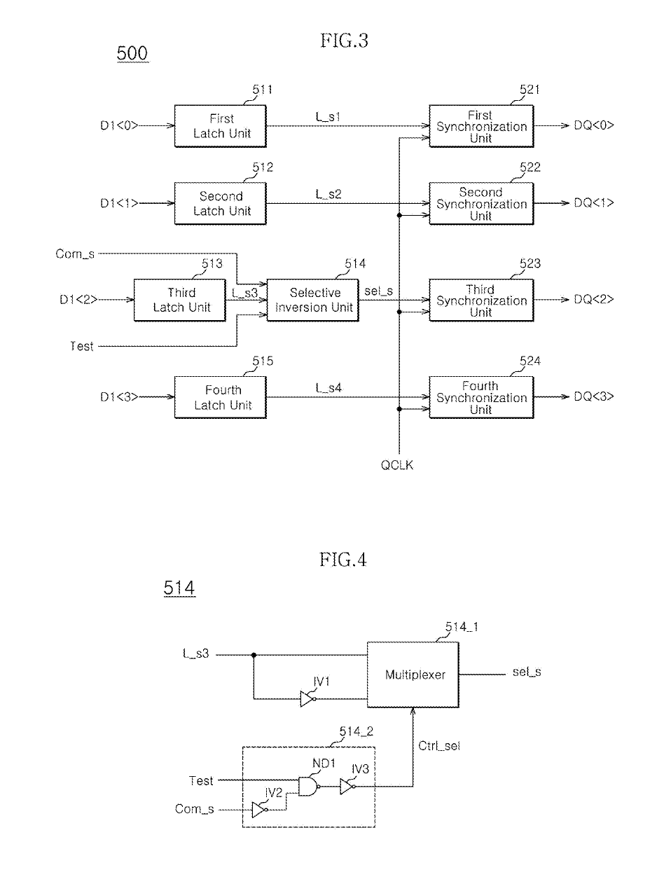

As shown in FIG. 2, the timing control block 400 may include a shift register 410 and a latch unit 420.

The shift register 410 may be configured to delay the latency signal Latency_s by the predetermined cycle of the clock CLK, and generate a delayed latency signal Latency_D. The time by which the shift register 410 delays the latency signal Latency_s may beset to be the same as the time that is required for the data comparison block 300 to compare the plurality of first data D1<0:3> and the plurality of second data D2<0:3>.

The latch unit 420 may be configured to latch the comparison result signal Result_com in response to the delayed latency signal Latency_D, and output the latched signal as the to comparison signal Com_s.

As shown in FIG. 3, the data output block 500 may include first to fourth latch units 511, 512, 513 and 515, a selective inversion unit 514, and first to fourth synchronization units 521 to 524. The plurality of first data D1<0:3> may include first first data D1<0>, second first data D1<1>, third first data D1<2> and fourth first data D1<3>. The plurality of output data DQ<0:3> may include first output data DQ<0>, second output data DQ<1>, third output data DQ<2> and fourth output data DQ<3>.

The first latch unit 511 may be configured to latch the first first data D1<0> and output a first latch signal L_s1.

The second latch unit 512 may be configured to latch the second first data D1<1> and output a second latch signal L_s2.

The third latch unit 513 may be configured to latch the third first data D1<2> and output a third latch signal L_s3.

The fourth latch unit 515 may be configured to latch the fourth first data D1<3> and output a fourth latch signal L_s4.

The selective inversion unit 514 may be configured to determine whether to invert the third latch signal L_s3, in response to the comparison signal Com_s when the test signal Testis enabled, and generate a select signal sel_s. In the case where the test signal Testis enabled, the selective inversion unit 514 may output the select signal sel_s by inverting the third latch signal L_s3 when the comparison signal Com_s is disabled, and may output the third latch signal L_s3 as the select signal sel_s when the comparison signal Com_s is enabled. In the case where the test signal Testis disabled, the selective inversion unit 514 may output the third latch signal L_s3 as the select signal sel_s regardless of the comparison signal Com_s.

The first synchronization unit 521 may be configured to output the first output data DQ<0> by synchronizing the first latch signal L_s1 with a clock QCLK for outputting.

The second synchronization unit 522 may be configured to output the second output data DQ<1> by synchronizing the second latch signal L_s2 with the clock QCLK for outputting.

The third synchronization unit 523 may be configured to output the third output data DQ<2> by synchronizing the select signal sel_s with the clock QCLK for output.

The fourth synchronization unit 524 may be configured to output the fourth output data DQ<3> by synchronizing the fourth latch signal L_s4 with the clock QCLK for outputting.

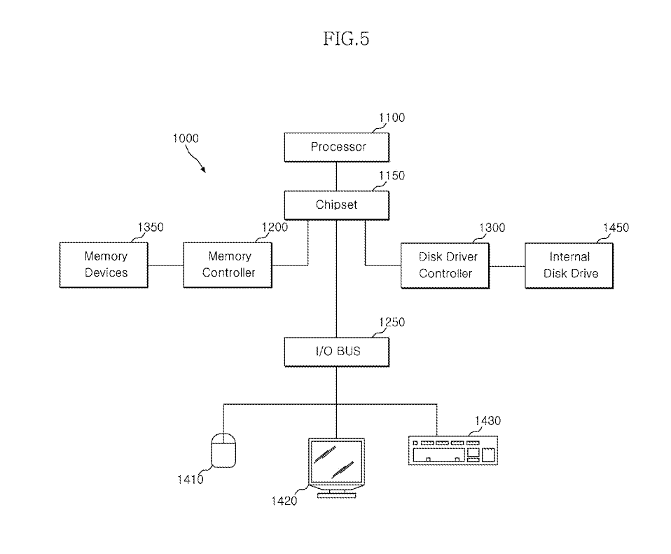

As shown in FIG. 4, the selective inversion unit 514 may include a multiplexer 514_1, a selection control section 514_2, and a first inverter IV1.

The first inverter IV1 inverts the third latch signal L_s3.

The multiplexer 514_1 may be configured to output the third latch signal L_s3 as the select signal sel_s or output the inverted signal of the third latch signal L_s3, that is, the output signal of the first inverter IV1, as the select signal sel_s, in response to a selection control signal Ctrl_sel. For example, the multiplexer 514_1 may output the output signal of the first inverter IV1 as the select signal sel_s when the selection control signal Ctrl_sel is enabled, and may output the third latch signal L_s3 as the select signal sel_s when the selection control signal Ctrl_sel is disabled.

The selection control section 514_2 may be configured to enable the selection control signal Ctrl_sel only when the test signal is Testis enabled and the comparison signal Com_s is disabled. Also, the selection control section 514_2 may be configured to disable the selection control signal Ctrl_sel when the test signal Testis disabled or when the test signal Testis enabled and the comparison signal Com_s is enabled.

The selection control section 514_2 may include second and third inverters IV2 and IV3, and a NAND gate ND1. The second inverter IV2 receives the comparison signal Com_s. The NAND gate ND1 receives the test signal Test and the output signal of the second inverter IV2. The third inverter IV3 receives the output signal of the NAND gate ND1 and outputs the selection control signal Ctrl_sel.

Operations of the semiconductor memory apparatus in accordance with the embodiments, configured as mentioned above, will be described below.

In the test or test mode, the same data may be stored in the semiconductor memory apparatus.

Referring to FIG. 1, the same data is stored in the first and second data storage regions 100 and 200 which is included in the semiconductor memory apparatus. Thereafter, the data stored in the first and second data storage regions 100 and 200 may be outputted.

The data comparison block 300 may perform a comparison to know whether the data outputted from different data storage regions 100 and 200, that is, the first and second data storage regions 100 and 200, are the same or not. In detail, the data comparison block 300 may perform a comparison to know whether the plurality of first data D1<0:3> (the data outputted from the first data storage region 100) and the plurality of second data D2<0:3> (the data outputted from the second data storage region 200) are all the same with each other. The data comparison block 300 may generate the comparison result signal Result_com which may been abled, when the plurality of first data D1<0:3> and the plurality of second data D2<0:3> are all the same. The data comparison block 300 may generate the comparison result signal Result_com which may be disabled, when even one data of the plurality of first data D1<0:3> and the plurality of second data D2<0:3> is different.

The timing control block 400 may delay the latency signal Latency_s by the predetermined cycle of the clock CLK, and may latch the comparison result signal Result_com. In detail, referring to FIG. 2, the timing control block 400 may delay the latency signal Latency_s by the predetermined cycle of the clock CLK, and may generate the delayed latency signal Latency_D. The timing control block 400 may latch the comparison result signal Result_comin response to the delayed latency signal Latency_D, and may output the comparison signal Com_s. The timing control block 400 may output the comparison result signal Result_com as the comparison signal Com_s at a timing that is delayed by the predetermined cycle of the clock CLK from the timing of the latency signal Latency_s.

The data output block 500 may output the plurality of first data D1<0:3> which are outputted from the first data storage region 100, as the plurality of output data DQ<0:3>, not in the test. In the test or test mode, the data output block 500 may determine whether to invert the data D1<2> specified among the plurality of first data D1<0:3>, in response to the comparison signal Com_s, and output the specified data D1<2>, which is determined in terms of whether to be inverted or not, and the plurality of first data D1<0:1> and D1<3>, which are left by excluding the specified data D1<2> among the plurality of first data D1<0:3>, as the plurality of output data DQ<0:3>.

This will be described by example below.

In the test or test mode, data all of which have a high level are stored in the first and second data storage regions 100 and 200 as different data storage regions.

If the data all of which have a “high” logic level are normally stored in the first and second data storage regions 100 and 200, all the plurality of first data D1<0:3> and the plurality of second data D2<0:3> have a “high” level.

Accordingly, since the plurality of first data D1<0:3> and the plurality of second data D2<0:3> are the same as the “high” level, the data comparison block 300 may output the comparison result signal Result_com which is enabled.

The timing control block 400 may delay the latency signal Latency_s by the same delay time as the data comparison time of the data comparison block 300, latch the comparison result signal Result_com in response to the delayed latency signal Latency_D, and may output the latched signal as the comparison signal Com_s.

The data output block 500 may output the plurality of output data DQ<0:3> by not inverting the specified data D1<2> among the plurality of first data D1<0:3> in response to the comparison signal Com_s which is enabled. In other words, the output data DQ<0:3> are outputted as data all of which have a “high” level.

Conversely, if there exists data which is not normally stored in the first and second data storage regions 100 and 200, all the plurality of first data D1<0:3> and the plurality of second data D2<0:3> are not the same with each other.

Accordingly, the data comparison block 300 may output the comparison result signal Result_com which is disabled.

The timing control block 400 may delay the comparison result signal Result_com by the comparison time for which the data comparison block 300 compares the plurality of first data D1<0:3> and the plurality of second data D2<0:3>, and may output the comparison signal Com_s which is disabled.

The data output block 500 may invert the specified data D1<2> among the plurality of first data D1<0:3> in response to the comparison signal Com_s, and may output the remaining data D1<0:1> and D1<3> and the inverted specified data D1<2> as the plurality of output data DQ<0:3>. Therefore, one data of the plurality of output data DQ<0:3> may be outputted as data with a value different from the remaining data.

In the normal operation, that is, not in the test or test mode, the data output block 500 may output the plurality of first data D1<0:3> which are outputted from the first data storage region 100.

As is apparent from the above descriptions, because the semiconductor memory apparatus in accordance with the embodiments may be configured to output a result of comparing the data outputted from different data storage regions, in a test or test mode, by using a data output block which outputs the data of one data storage region among a plurality of data storage regions not in a test or test mode, the number of additional circuits to be used in a test or test mode may be minimized. Also, because the semiconductor memory apparatus may be configured to normally latch a test result (a data comparison result) by delaying a time to latch the test result, by a time that is required to compare the data outputted from the different data storage regions, it may be possible to output a normal test result, whereby the reliability of the semiconductor memory apparatus may be improved.

The semiconductor memory apparatus discussed above is particular useful in the design of memory devices, processors, and computer systems. For example, referring to FIG. 5, a block diagram of a system employing a semiconductor memory apparatus in to accordance with the embodiments of the invention is illustrated and generally designated by a reference numeral 1000. The system1000 may include one or more processors or central processing units (“CPUs”) 1100. The CPU1100 may be used individually or in combination with other CPUs. While the CPU1100 will be referred to primarily in the singular, it will be understood by those skilled in the art that a system with any number of physical or logical CPUs may be implemented.

A chipset 1150 may be operably coupled to the CPU1100. The chipset 1150 is a communication pathway for signals between the CPU1100 and other components of the system1000, which may include a memorycontroller1200, an input/output (“I/O”) bus 1250, and a disk drive controller1300. Depending on the configuration of the system, any one of a number of different signals may be transmitted through the chipset 1150, and those skilled in the art will appreciate that the routing of the signals throughout the system1000 can be readily adjusted without changing the underlying nature of the system.

As stated above, the memorycontroller1200 may be operably coupled to the chipset 1150. The memory controller 1200 may include at least one semiconductor memory apparatus as discussed above with reference to FIGS. 1-4. Thus, the memory controller 1200 can receive a request provided from the CPU 1100, through the chipset 1150. In alternate embodiments, the memory controller 1200 may be integrated into the chipset 1150. The memorycontroller1200 may be operably coupled to one or more memory devices 1350. In an embodiment, the memory devices 1350 may include the semiconductor memory apparatus discussed above with relation to FIGS. 1-4, the memory devices 1350 may include a plurality of word lines and a plurality of bit lines for defining a is plurality of memory cell. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller1450 (i.e., internal disk drive) may also be operably coupled to the chipset 1150. The disk drive controller1450 may serve as the communication pathway between the chipset 1150 and one or more internal disk drives 1450. The internal disk drive 1450 may facilitate disconnection of the external data storage devices by storing both instructions and data. The disk drive controller1300 and the internal disk drives 1450 may communicate with each other or with the chipset 1150 using virtually any type of communication protocol, including all of those mentioned above with regard to the I/O bus 1250.

It is important to note that the system1000 described above is in relation to FIG. 5 is merely one example of a system employing the semiconductor memory apparatus as discussed above with relation to FIGS. 1-4. In alternate embodiments, such as cellular phones or digital cameras, the components may differ from the embodiments shown in FIG. 5.

While various embodiments have been described above, it will be understood to those skilled in the art that the embodiments described are by way of example only. Accordingly, the semiconductor memory apparatus and the test method using the same described herein should not be limited based on the described embodiments. Rather, the semiconductor memory apparatus and the test method using the same described herein should only be limited in light of the claims that follow when taken in conjunction with the above description and accompanying drawings.

What is claimed is:

1. A semiconductor memory apparatus comprising:
first data outputted from a first data storage region;
second data outputted from a second data storage region;
a data comparison block configured to perform a comparison to determine whether the first data and the second data are the same, and generate a comparison result signal;
a timing control block configured to latch the comparison result to signal in response to a clock and a latency signal, and output a comparison signal; and
a data output block configured to receive a test signal and invert the first data in response to the comparison signal and output output data.

2. The semiconductor memory apparatus according to claim 1, wherein:
the data output block is configured to operate in a test mode in response to the test signal and invert the first data in response to the comparison signal and output the output data; and
the data output block is configured to operate in a normal mode while not in the test mode and output the first data as the output data.

3. The semiconductor memory apparatus according to claim 1, wherein the timing control block comprises:
a shift register configured to delay the latency signal by a predetermined cycle of the clock, and generate a delayed latency signal; and
a latch unit configured to latch the comparison result signal in response to the delayed latency signal, and output a latched signal as the comparison signal.

4. The semiconductor memory apparatus according to claim 2, wherein the data output block comprises:
a latch unit configured to latch the first data, and output a latch signal;
a selective inversion unit configured to invert or non-invert the latch signal in response to the comparison signal in the test mode, and output a select signal; and
a synchronization unit configured to output the select signal as the output data in synchronization with a clock.

5. A semiconductor memory apparatus comprising:
a data comparison block configured to determine whether a plurality of first data and a plurality of second data are the same, and generate a comparison result signal;
a timing control block configured to latch the comparison result signal in response to a clock and a latency signal, and output a comparison signal; and
a data output block configured to determine whether to invert specified data among the plurality of first data, in response to the comparison signal, and output the specified data determined in terms of whether to be inverted or not and the first data which are left by excluding the specified data determined in terms of whether to be inverted or not, as output data, in a test.

6. The semiconductor memory apparatus according to claim 5, wherein the data output block outputs the plurality of first data as the output data when not in the test.

7. The semiconductor memory apparatus according to claim 6, wherein the data output block comprises:
a plurality of latch units configured to latch the plurality of first data, and generate a plurality of latch signals;
a selective inversion unit configured to invert or non-invert the latch signal which is generated by latching the specified data, in response to the comparison signal in the test, and output a select signal; and
a plurality of synchronization units configured to output the select signal and the latch signals which are left by excluding the latch signal generated by latching the specified data, in synchronization with a clock.

8. The semiconductor memory apparatus according to claim 7, wherein the selective inversion unit comprises:
a selection control section configured to enable a selection control signal only when a test signal is enabled and the comparison signal is disabled; and
a multiplexer configured to output one of the latch signal generated by latching the specified data and an inverted signal of the latch signal generated by latching the specified data, as the select signal in response to the selection control signal.

9. The semiconductor memory apparatus according to claim 5, wherein the data output block outputs the first data as the output data when not in the test.

10. The semiconductor memory apparatus according to claim 5, wherein the timing control block comprises:
a shift register configured to delay the latency signal by a predetermined cycle of the clock, and generate a delayed latency signal; and
a latch unit configured to latch the comparison result signal in response to the delayed latency signal, and output a latched signal as the comparison signal.

11. A method for testing a semiconductor memory apparatus, comprising:
storing the same data in a plurality of data storage regions;
determining whether data stored in different data storage regions are the same and providing a result;
delaying a latency signal by a predetermined cycle of a clock; and
latching the result of the determining and outputting a latched result, in response to a delayed latency signal.

12. The method according to claim 11, wherein outputting the latched result comprises:
a normal output action in which data outputted from one data storage region among the plurality of data storage regions are outputted when not in a test; and
a test output action to determine whether to invert specified data among the data outputted in the normal output action in response to the result of determining whether data stored in the different data storage regions are the same, and the specified data determined in terms of whether to be inverted or not and data left by excluding the specified data and outputted in the normal output action are outputted when in the test.
